(19) United States
(12) Patent Application Publication
(10) Pub. No.: US 2011/0147596 A1
(43) Pub. Date: Jun. 23, 2011

(54) PHOTOELECTRIC CONVERSION DEVICE AND RADIATION DETECTION DEVICE

(75) Inventors: Yukimasa Ishida, Nagano (JP); Takashi Sato, Nagano (JP); Yasushi Yamazaki, Nagano (JP)

(73) Assignee: SONY CORPORATION, Tokyo (JP)

(21) Appl. No.: 12/987,224

(22) Filed: Jan. 10, 2011

(30) Foreign Application Priority Data
Jun. 26, 2008 (JP) P2008-167447

(51) Int. Cl. G01T 1/20; H01L 27/146; G01T 1/17

(52) U.S. Cl. 250/366; 250/208.1; 250/394

(57) ABSTRACT

A photoelectric conversion device is provided and includes: a photoelectric conversion panel in which light detection portions each having a charge storage portion storing light as electric charges are two-dimensionally arranged; a reading control unit that reads the electric charges stored in the charge storage portions of the photoelectric conversion panel for each reading signal line; and a reset unit that is connected to the reading signal lines and discharges residual charges of the charge storage portions for each reading signal line. The reading control unit and the reset unit are arranged at different end portions of the photoelectric conversion panel.

### BACKGROUND

The present disclosure relates to a photoelectric conversion device including a photoelectric conversion panel in which light detection portions each having a charge storage element are arranged in a matrix shape, a reading control unit that reads electric charges stored in the charge storage elements of the photoelectric conversion panel through reading signal lines, and a reset unit that resets residual charges of the charge storage elements, and a radiation detection device employing the photoelectric conversion device.

Recently, regarding radiography for medical treatment, nondestructive inspection, and the like, a computed radiography (CR) method of reading and digitalizing a radiation image radiated by a laser or from an image recording sheet having X-ray radiation information recorded on a plate on which photo-stimulable phosphors called cassettes are formed and a digital radiography (DR) method using an indirect-conversion digital radiation imaging device (FPD: Flat Panel Detector) in which a scintillator converting a radiation ray into a visible ray is formed on a two-dimensional image sensor plate in which photoelectric conversion elements such as PIN elements or MIS elements and TFT active switches are combined or a direct-conversion FPD in which a material such as a-Se directly converting a radiation ray in a photoelectric conversion manner and TFT active switches are combined have been developed from analog techniques using a silver halide film and have been provided for actual use.

Such FPDs can expose a large area at an equal magnification with a resolution of 70 to 200 μm. The FPDs can be classified into two types of a fixed type in which an FPD is mounted on a relatively large system such as a general see-through imaging apparatus, a CT apparatus, or an angio system and a portable type in which an FPD can be carried to a patient along with an X-ray source and can be installed in situ.

Regarding such FPDs, it is necessary to detect a lesion remaining dormant in biological tissues or foreign matter in an object sensitively and it is necessary to generate an image by reading an X-ray image as digital data of 12 to 16 bits or more and further processing the digital data. Accordingly, it is important to improve the S/N ratio which is a ratio of the original image signal (signal component) and the other signal (noise component). In order to improve the S/N ratio, it is necessary to decrease the noise component and to increase the signal component.

It is known that the noise signal results from thermal noise or parasitic capacitance due to line resistance, element-fixed variations of an amplification circuit system of a read image signal (an integral circuit, a correlated double sampling (CDS) circuit, a multiplexer circuit, and the like), characteristic variations of TFT active switches, and the like. Various techniques and ideas for reducing and canceling noise have been invented.

On the other hand, various techniques for increasing the image signal (signal component) to be acquired have been developed as a result of steady efforts. A representative example thereof is an active pixel type in which a reading amplification transistor is disposed in a pixel shown in FIG. 8A, such as a CMOS image sensor.

In the active pixel type, as shown in FIG. 8A, electric charges generated in a photoelectric conversion element 100 disposed in each pixel and formed of, for example, a PIN photo diode are stored in a parasitic capacitor of the photoelectric conversion element or an auxiliary capacitor 101 independently provided to improve the dynamic range, a small amount of potential resulting from a variation in capacitance at that time is amplified by an amplification transistor 102 disposed in each pixel, and the amplified amount of potential is read to a signal line 104 by the use of a switching transistor 103, whereby the signal component greater than the noise component generated in paths extending from the pixels to a reading driver at the time of reading signals can be taken to a reading driver. In FIG. 8A, reference numeral 105 represents a scanning line for driving the gate of a switching transistor, reference numeral 106 represents a reset transistor, and reference numeral 107 represents a reset line.

On the other hand, the a-Si TFT process having been performed in liquid crystal devices for a long time is often followed by a large-sized TFT substrate (microgiant device) used in a large-sized FPD. In order to reduce the line resistance or the line capacitance by reducing the number of lines or line intersections or to reduce the noise component as much as possible and to improve the aperture ratio or the yield by simplifying the pixel structure, the line-drawing structure, and the mounting terminals, as shown in FIG. 8B, a so-called passive pixel type having a simplified configuration has been mainly used in which a photoelectric conversion element 111 formed of, for example, a PIN photo diode and an auxiliary capacitor 112 corresponding to the specification of the dynamic range are connected in parallel without providing an amplification transistor to each pixel, one end of the parallel circuit is supplied with a bias potential Vb, the other end thereof is connected to a signal line 114 via a row-selecting TFT 113, and the gate of the row-selecting TFT 113 is connected to a scanning line 115.

In this case, by sequentially turning on row-selecting TFT switches by the use of a row-selecting driver IC including a shift register circuit, optical signal charges generated through the photoelectric conversion of the pixels and stored in the parasitic capacitor or the auxiliary capacitor of the photoelectric conversion elements pass through the signal lines 114 via the row-selecting TFTs 113 of the pixels and are integrated/amplified by a reading amplifier disposed for each column, and the analog signals of each column are serialized by the multiplexer circuit, are digitalized into image signals of 12 to 16 bits or more by the A/D converter, and are then transmitted to a predetermined image processor. Since the signals read through this reading path include noise signal components due to the reading path in addition to the image signals, it is not desirable to amplify the signals as they are. For example, a method of canceling the noise signal components and reading the image signals by providing a correlated double sampling circuit to the reading amplifier, independently reading the noise components generated due to the path from the pixels to the reading driver IC, and acquiring the difference therebetween is widely known.

In order to reduce or cancel the noise of the reading path using the above-mentioned method, it is also necessary to consider the reading remnants of the charges stored in the photoelectric conversion elements or the independently added auxiliary capacitors. For example, in a radiographic apparatus such as an indirect-conversion FPD, the X-ray radiated from an X-ray source and transmitted through an examination object in response to an X-ray radiation request signal is converted into a visible ray with the light intensity corresponding to the amount of transmitted X-rays by a scintillator formed of cesium iodide CsI or gadolinium oxysulfide (GOS) and doped with sodium or thallium, the visible ray is stored as an amount of charges corresponding to the light intensity by the photoelectric conversion elements (for example, PIN photo diode), the radiation of X-rays is stopped, the row-selecting TFTs are sequentially turned on by the independent row-selecting driver (gate driver) IC, the amount of charges stored in the pixels are read as X-ray image signals. At this time, when a previously-captured image remains as charges in the pixels, the previously-captured image overlaps with the presently-captured image, and therefore, it is difficult to acquire an image correctly. Accordingly, a method of initializing (resetting) the pixels and removing noise by acquiring dark image data once or plural times before the radiation of X-rays or after the reading of an image and subtracting the dark image data is known.

However, such a method is not desirable because it takes time to extract residual charges as a dark image due to the on resistance of the row-selecting TFT and the PIN capacitance or the auxiliary capacitance and a patient as an examination object is forced to wait for a time in order to carry out a dark image acquiring sequence before the radiation of X-rays on the spot for medical treatment. As a method of shortening the reading time of the storage image, for example, a method of turning on all the scanning lines before storing signal charges due to the radiation of X-rays to remove (reset) the residual charges of the pixels is disclosed in JP-A-9-131337.

The method of forcibly resetting charges stored in the photoelectric conversion elements or the auxiliary capacitors without reading the previously-captured image is generally used in active pixel type CMOS image sensors. In the most basic example, as shown in FIG. 8A, each pixel includes three transistors of a row-selecting transistor 103, an amplification transistor 102, and a reset transistor 106 and a photo diode 100 (further including an auxiliary capacitor 101 as needed) and the influence of the previously-captured image is frequently cancelled for each pixel by sequentially performing processes of resetting→exposure (storage of charges)→reading. Recently, a configuration in which each pixel includes four transistors is known to be an improvement thereof

### SUMMARY

However, in the example of a passive pixel type described in JP-A-9-131337, there is a problem in that it is difficult to uniformly eject the charges which are different depending on pixels only for the reason that it is faster than the sequential blank reading method. When a dark image is acquired after radiating X-rays and reading an image, a doctor forces a patient to wait for a time, which is not desirable.

On the other hand, when the active pixel type is employed, it is necessary to arrange many transistors in a pixel, micro processes such as CMOS-LSI processes are fully grown, and it is possible to produce an image sensor with a small size and a small pixel pitch having a reading driver IC built therein, which are significant. However, in a large-area FPD using an a-Si TFT with an electron mobility of about 0.1 to 0.8 cm²/Vs as a pixel transistor, since W of each TFT is not reduced any more, the pixel layout is necessarily restricted. In addition, since the number of lines increases with the increase in panel size, it is not easy to employ the active pixel type for the large-sized FPD from the viewpoint of the increase in noise and the yield. It may be considered that an LTPS is used instead of the a-Si TFT. However, since the restriction of the large width of a linear excimer laser beam used in the course of crystallization or the variation in TFT characteristics (such as a threshold voltage Vth, on current, off current, an S value, and an electron mobility) due to the variation in laser energy applied to an a-Si film as a precursor is two-dimensionally caused in micro and macro scales, it is not actually easy to produce a large-area active matrix substrate with uniform structures in a plane using the LTPS. In addition, there is a problem in that the LTPS having a large number of processes and using special equipment including maintenance is disadvantageous in manufacturing cost and it is difficult to provide an FPD at a low cost.

Thus, it is desirable to provide a photoelectric conversion device and a radiation detection device which can satisfactorily reset residual charges by employing a photoelectric conversion portion with a simple structure.

According to an embodiment, there is provided a photoelectric conversion device including: a photoelectric conversion panel in which light detection portions each having a charge storage portion storing light as electric charges are two-dimensionally arranged; a reading control unit that reads the electric charges stored in the charge storage portions of the photoelectric conversion panel for each reading signal line; and a reset unit that is connected to the reading signal lines and discharges residual charges of the charge storage portions for each reading signal line. Here, the reading control unit and the reset unit are arranged at different end portions of the photoelectric conversion panel.

According to this photoelectric conversion device, since the reset unit is connected to the reading signal lines connected to the reading control unit of the photoelectric conversion panel and the reading control unit and the reset unit are disposed at different ends of the photoelectric conversion panel, it is possible to satisfactorily remove the charges remaining in the charge storage portions by the use of the reset unit for each reading signal line. Since the reading control unit and the reset unit are located apart from each other, it is possible to satisfactorily prevent the noise generated in the reset unit from having an influence on the reading control unit at the time of resetting.

In the photoelectric conversion device, the reset unit may be arranged on the opposite side of the reading control unit with the photoelectric conversion panel interposed therebetween.

According to this photoelectric conversion device, since the reset unit and the reading control unit are arranged to face each other with the photoelectric conversion panel interposed therebetween, it is possible to increase the distance therebetween and thus to reduce the influence of the noise generated in the reset unit on the reading control unit.

According to another embodiment, there is provided a photoelectric conversion device including: a photoelectric conversion panel in which light detection portions each having a charge storage portion storing light as electric charges are two-dimensionally arranged; a reading control unit that reads the electric charges stored in the charge storage portions of the photoelectric conversion panel for each reading signal line; and a reset unit that is connected to the reading signal lines and discharges residual charges of the charge storage portions for each reading signal line. Here, the reading control unit and the reset unit have different circuit configurations.

According to this photoelectric conversion device, it is possible to satisfactorily remove the charges remaining in the charge storage portions by the use of the reset unit. Since the reading control unit and the reset unit connected to each other via the reading signal lines have different circuit configurations, it is possible to satisfactorily prevent the noise generated in the reset unit from having an influence on the reading control unit.

In the photoelectric conversion device, the reset unit may be built in the photoelectric conversion panel.

In this photoelectric conversion device, since the reset unit is built in the photoelectric conversion panel, it is possible to simplify the circuit configuration by as much.

In the photoelectric conversion device, each light detection portion may include a parallel circuit in which a light detection element and a charge storage element are connected in parallel and the parallel circuit may include an end supplied with a bias potential and the other end connected to the corresponding reading signal line via a switching element.

According to this photoelectric conversion device, since the light detection portion has the configuration of a passive pixel type, it is possible to simplify the configuration of the light detection portion and thus to decrease the size of the entire configuration.

In the photoelectric conversion device, the reset unit may include switches which are individually interposed between the reading signal lines and a reset power source and may control the switches to simultaneously be turned on at the time of resetting.

According to this photoelectric conversion device, since the reset unit includes the switches independently interposed between the reading signal lines and the reset power source and the switches are simultaneously turned on at the time of resetting, it is possible to reset the charges remaining in the charge storage portions of the light detection portions in the photoelectric conversion panel for a short time.

In the photoelectric conversion device, the reset power source may be commonly used as a bias power source and the length of bias lines may be equal to the length of the reading signal lines.

According to this photoelectric conversion device, it is possible to use the bias power source and the reset power source in common and thus to simplify the entire circuit configuration.

In the photoelectric conversion device, the potential of a bias power source may be set to be higher than the potential of the reset power source.

According to this photoelectric conversion device, it is possible to apply a forward bias to the light detection elements by setting the bias potential to be higher than the reset potential, and thus to rapidly eject the charges remaining in the charge storage elements.

In the photoelectric conversion device, each light detection element may be formed of one of a PIN element and an MIS element.

According to this photoelectric conversion device, since the PIN element or the MIS element is used as the light detection element, it is possible to satisfactorily convert the applied visible ray into an electrical signal.

According to another embodiment, there is provided an autoradiographic apparatus including: any one of the above-mentioned photoelectric conversion devices; and a scintillator that is disposed on a light detection face of the photoelectric conversion panel of the photoelectric conversion device so as to convert a radiation ray into a visible ray.

According to this autoradiographic apparatus, it is possible to store the charges corresponding to a radiation image in the charge storage portions by converting a radiation into a visible ray by the use of the scintillator and photoelectrically converting the visible ray by the use of the photoelectric conversion panel of the photoelectric conversion device, and to obtain radiation image data by reading the charges from the charge storage portions by the use of the reading control unit. It is possible to satisfactorily remove the charges remaining in the charge storage portions by the use of the reset unit and to satisfactorily prevent the previously-captured radiation image from remaining

According to another embodiment, there is provided a radiation detection device including: a radiation detection panel in which radiation detection portions each having a charge storage portion storing a radiation ray as electric charges are two-dimensionally arranged; a reading control unit that reads the electric charges stored in the charge storage portions of the radiation detection panel for each reading signal line; and a reset unit that is connected to the reading signal lines and discharges residual charges of the charge storage portions for each reading signal line. Here, the reading control unit and the reset unit are arranged at different end portions of the radiation detection panel.

According to this radiation detection device, by storing the charges corresponding to the amount of radiation in the charge storage portions in the radiation detection portions which are two-dimensionally arranged in the radiation detection panel and reading the stored charges by the use of the reading control unit, it is possible to read the radiation image data and to satisfactorily remove the charges remaining in the charge storage portions by the use of the reset unit. At this time, it is possible to satisfactorily prevent the noise generated in the reset unit from having an influence on the reading control unit and to satisfactorily prevent the previously-captured radiation image from remaining

In the radiation detection device, the reset unit may be built in the radiation detection panel.

According to this radiation detection device, since the reset unit is built in the radiation detection panel, it is possible to simplify the entire circuit configuration by as much.

In the radiation detection device, each radiation detection portion may include a parallel circuit in which a radiation detection element and a charge storage element are connected in parallel and the parallel circuit may include an end supplied with a bias potential and the other end connected to the corresponding reading signal line via a switching element.

According to this radiation detection device, since the radiation detection portion has the configuration of a passive pixel type, it is possible to simplify the configuration of the radiation detection portion, thereby reducing the entire configuration size.

Additional features and advantages are described herein, and will be apparent from the following Detailed Description and the figures.

### BRIEF DESCRIPTION OF THE FIGURES

FIG. 1 is a plan view illustrating an autoradiographic apparatus according to an embodiment.

FIG. 2 is a block diagram illustrating the circuit configuration of the autoradiographic apparatus shown in FIG. 1.

FIG. 3 is a front view illustrating a portable case receiving the autoradiographic apparatus.

FIG. 4 is a diagram illustrating a radiation imaging state.

FIG. 5 is a block diagram illustrating the configuration of an autoradiographic apparatus according to another embodiment.

FIG. 6 is a sectional view illustrating a radiation detection device according to another embodiment.

FIG. 7 is a block diagram illustrating the circuit configuration of the radiation detection device shown in FIG. 5.

FIGS. 8A and 8B are circuit diagrams illustrating the circuit configuration of a pixel in the related art, where FIG. 8A is a circuit diagram illustrating an active pixel type and FIG. 8B is a circuit diagram illustrating a passive pixel type.

### DETAILED DESCRIPTION

Hereinafter, embodiments will be described with reference to the accompanying drawings.

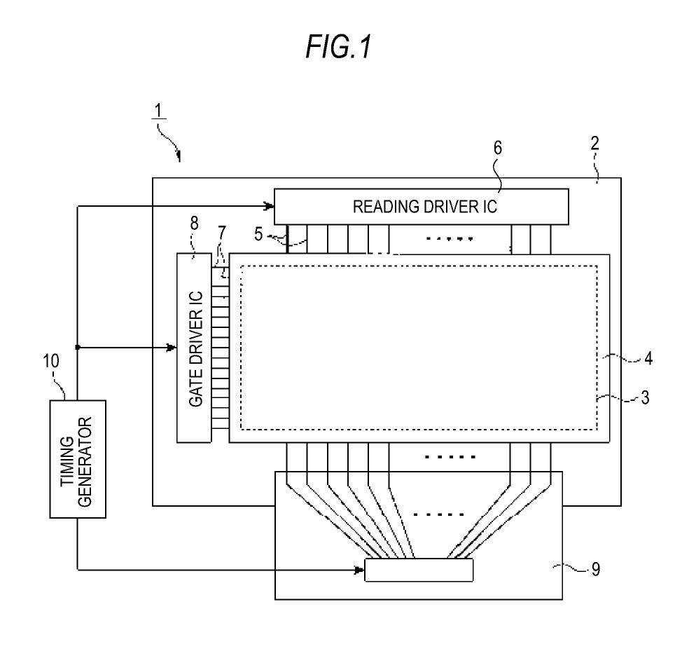

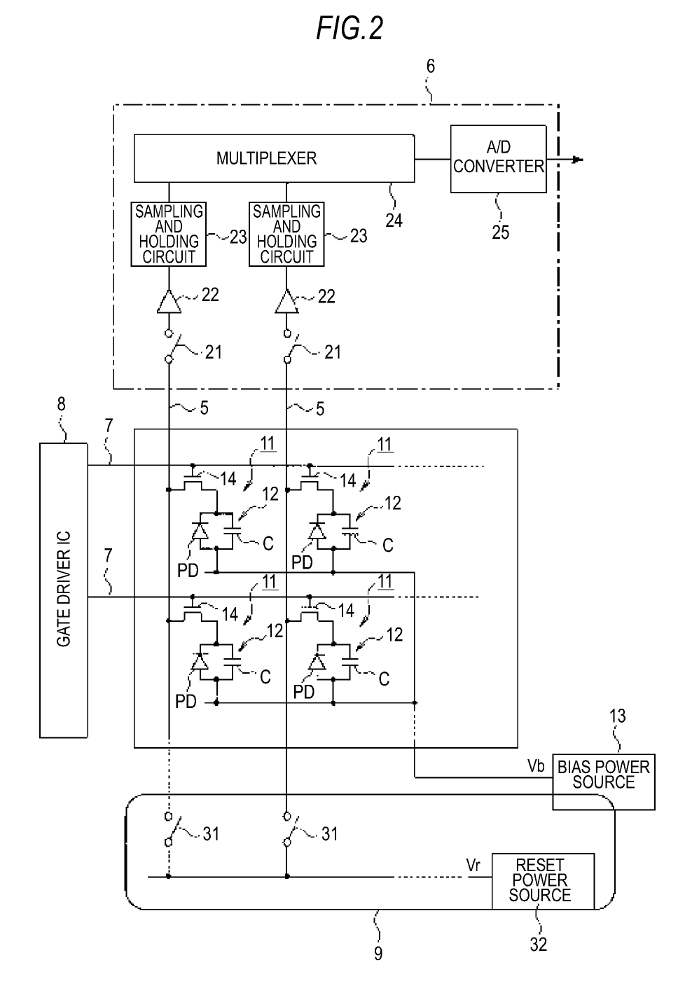

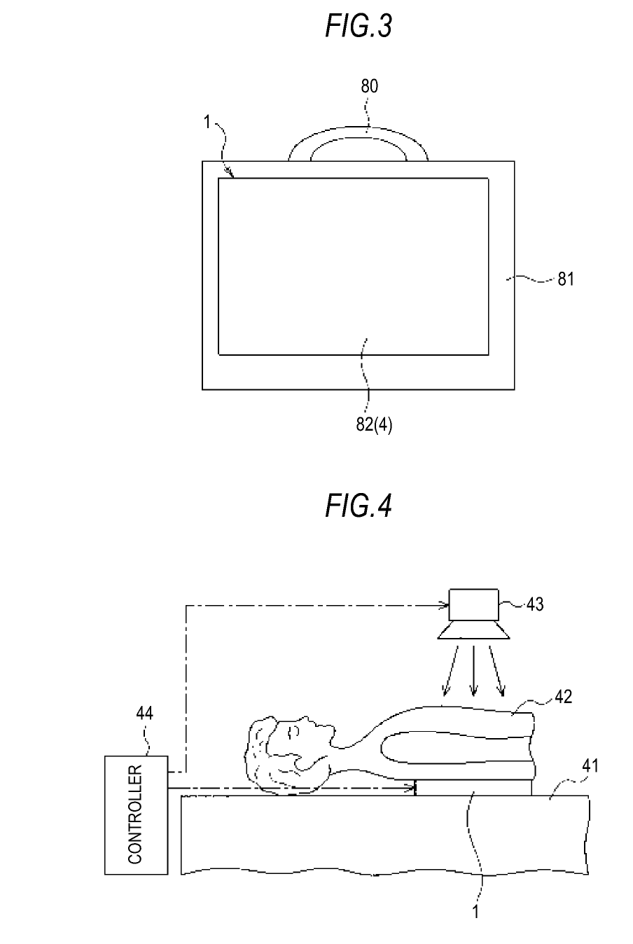

FIG. 1 is a plan view illustrating an autoradiographic apparatus according to an embodiment. FIG. 2 is a block diagram illustrating the circuit configuration of the autoradiographic apparatus shown in FIG. 1. FIG. 3 is a front view illustrating a portable case receiving the autoradiographic apparatus.

In FIG. 1, an autoradiographic apparatus 1 includes a photoelectric conversion panel 2 and a scintillator 4 that covers a photoelectric conversion area 3 formed on the top surface of the photoelectric conversion panel 2 and that converts a radiation (X-ray) into a visible ray.

A reading driver IC 6 as the reading control unit is connected to reading signal lines 5 formed in the photoelectric conversion panel 2, and a gate driver IC 8 including, for example, a shift register and outputting a row-selecting signal is connected to row-selecting signal lines 7 formed in the photoelectric conversion panel 2.

A reset circuit 9 as the reset unit is connected on the opposite side of the reading signal lines 5 with the photoelectric conversion area 3 interposed between the reading driver IC 6 and the reset circuit. The reading driver IC 6, the gate driver IC 8, and the reset circuit 9 are supplied with timing signals from a timing generator 10.

As shown in FIG. 2, pixels 11 of a passive pixel type are two-dimensionally arranged in a matrix shape in the photoelectric conversion area 3 of the photoelectric conversion panel 2. Each pixel 11 includes a parallel circuit 12 in which a PIN photo diode PD and a capacitor C as the charge storage portion storing charges are connected in parallel. An end of the parallel circuit 12 is supplied with a predetermined bias potential Vb from a bias power source 13 via a bias line 15, and the other end is connected to the corresponding reading signal line 5 via a switching transistor 14 which is formed of a TFT. The gate of the switching transistor 14 is connected to the gate driver IC 8 via the corresponding row-selecting signal line 7.

As shown in FIG. 2, the reading driver IC 6 includes sense amplifiers 22 that are connected to ends of the reading signal lines 5 via reading switches 21, respectively, sampling and holding circuits 23 that sample and hold the amplification outputs of the sense amplifiers 22, a multiplexer 24 that receives the sampling and holding values of the sampling and holding circuits 23 as inputs in parallel and outputs serial image data, and an A/D converter 25 that converts the serial image data of the multiplexer 24 into digital values. The A/D converter 25 outputs digital image data of 12 to 16 bits or more to an external image display apparatus (not shown).

The reset circuit 9 includes a reset power source 32 that is connected to the other ends of the reading signal lines 5 via reset switches 31 and that has a reset potential Vr set therein. The reset switches 31 are controlled to simultaneously be turned on before the radiation of radiation rays in response to a timing signal supplied from the timing generator 10, and the reset potential Vr of the reset power source 32 is applied to the reading signal lines 5. Here, an MEMS switch can be preferably used as the reset switch so as to reduce the parasitic capacitance.

The autoradiographic apparatus 1 receives a scintillator 4 in a portable case 81 having a handle 80 so as to oppose a transparent protective sheet 82, as shown in FIG. 3.

The operations of the above-mentioned embodiment will be described below.

As shown in FIG. 4, the autoradiographic apparatus 1 is disposed on the lower side of, for example, a back of an examinee 42 lying upward in a bed 41, a radiation source 43 is disposed above the position opposed to the autoradiographic apparatus 1, and the autoradiographic apparatus 1 and the radiation source 43 are controlled by a controller 44.

At this time, the radiation source 43 is controlled in the off state by the controller 44 and an imaging standby signal is output to the timing generator 10 of the autoradiographic apparatus 1 by the controller 44 in the state where radiation rays are not radiated to the scintillator 4 of the autoradiographic apparatus 1. Accordingly, in the timing generator 10 of the autoradiographic apparatus 1, the reading switches 21 of the reading driver IC are controlled in the off state and the reset switches 31 of the reset circuit 9 are controlled in the off state. The outputting of the row-selecting signal output from the gate driver IC 8 is stopped.

In order to perform the autoradiography in this state, a reset start signal is output to the autoradiographic apparatus 1 from the controller 44. Accordingly, in the autoradiographic apparatus 1, a reset signal for simultaneously turning on the reset switches 31 of the reset circuit 9 is output by the timing generator 10 and the reset signal is also output to the gate driver IC. Accordingly, the reset switches of the reset circuit 9 are simultaneously controlled in the on state and an all-row selecting signal is output from the gate driver IC 8 so as to select all the pixels 11.

As a result, since the switching transistors 14 of all the pixels 11 are controlled in the on state, the reset power source 32 is connected to the cathodes of the PIN photo diodes PD and the ends of the capacitors C via the reset switches 31, the reading signal lines 5, and the switching transistors 14 of all the pixels 11.

Accordingly, the cathodes of the PIN photo diodes PD and the ends of the capacitors C closer to the switching transistors 14 have the reset potential Vr. On the other hand, the anodes of the PIN photo diodes PD and the other ends of the capacitors C are connected to the bias power source 13 and have the bias potential Vb.

As a result, since the residual charge storage states of the parasitic capacitors of the PIN photo diodes PD and the capacitors C in all the pixels are equal to each other, it is possible to satisfactorily prevent a random artifact from occurring due to the pixels having residual charges not read. At this time, the potentials in the reset state of the pixel 11 apart from the reset circuit 9 and the pixel close thereto have small difference due to the influence of the voltage drop in the line resistance of the reading signal lines 5. However, the influence is fixed-pattern noise and thus can be easily cancelled by means of image processing and the like.

Here, to rapidly eject the residual charges of the pixels 11, it is preferable that the reset potential Vr of the reset power source 32 is set to be smaller than the bias potential Vb of the bias power source 13 to apply a forward bias to the PIN photo diodes PD. In this case, it is not preferable that an excessive forward bias is applied to the PIN photo diodes PD. Accordingly, for example, when the bias potential is set to Vb=−2 V, the potential difference between both ends of each PIN photo diode PD can be preferably set to the range of 0.1 to 1 V by setting the reset potential to Vr=−2.1 to −3.0 V.

When the bias potential Vb and the reset potential Vr are set to the same value and the bias power source 13 and the reset power source 32 are commonly used, it is preferable that the length of the bias line 15 from the bias power source 13 to the parallel circuit 12 of the PIN photo diode PD and the capacitor C in each pixel 11 is set to be equal to the length of the signal line from the reset power source 32 to the parallel circuit 12 of each pixel 11.

When the resetting of the residual storage charges in each pixel 11 is finished in this way, the reset switches 31 of the reset circuit 9 are returned to the off state. Subsequently, a radiation emitting instruction to emit a radiation ray is output to the radiation source 43 from the controller 44 and the radiation ray is emitted to the examinee 42 for a predetermined time.

At this time, the radiation ray passing through the examinee 42 is radiated to the scintillator 4, the radiation ray is converted into a visible ray with the light intensity corresponding to the amount of emitted radiation ray by the scintillator 4, and the visible ray is applied to the pixels 11 of the photoelectric conversion area 3.

Accordingly, charges corresponding to the amount of visible rays are generated in the PIN photo diodes PD of each pixel 11 and are stored in its own parasitic capacitor and the capacitor C connected in parallel thereto. The reading switches 21 are controlled in the on state by the reading start signal supplied to the reading driver IC from the timing generator 10. By sequentially outputting the row-selecting signals from the gate driver IC 8 at the same time as outputting the reading start signal to the gate driver IC 8 from the timing generator 10, the switching transistors 14 of the pixels 11 in each row are turned on and the charges stored in the parasitic capacitors of the PIN photo diodes PD and the capacitors C are supplied to the reading driver IC 6 via the reading signal lines 5.

Accordingly, the charges are amplified by the sense amplifiers 22 of the reading driver IC 6 and sampled and held by the sampling and holding circuits 23, the sampled and held values are supplied as serial radiation image data to the A/D converter 25 by the multiplexer 24, and digital radiation image data is output to an external image display apparatus (not shown).

In this way, according to this embodiment, the reset circuit 9 is connected to the reading signal lines 5 of the pixels 11 and the reset circuit 9 is disposed on the opposite side of the reading driver IC 6 with the photoelectric conversion area 3 interposed therebetween. Accordingly, it is possible to satisfactorily prevent the noise generated at the time of turning on and off the reset switches 31 of the reset circuit 9 from having an influence on the reading driver IC 6. In addition, since the reading driver IC 6 and the reset circuit 9 are separated from each other, it is possible to more satisfactorily prevent the noise generated at the time of turning on and off the reset switches 31 of the reset circuit 9 from having an influence on the reading driver IC 6.

Although it has been described in the above-mentioned embodiment that the reset circuit 9 has an independent circuit configuration, the invention is not limited to this configuration, but the reset circuit may be built in the photoelectric conversion panel 2.

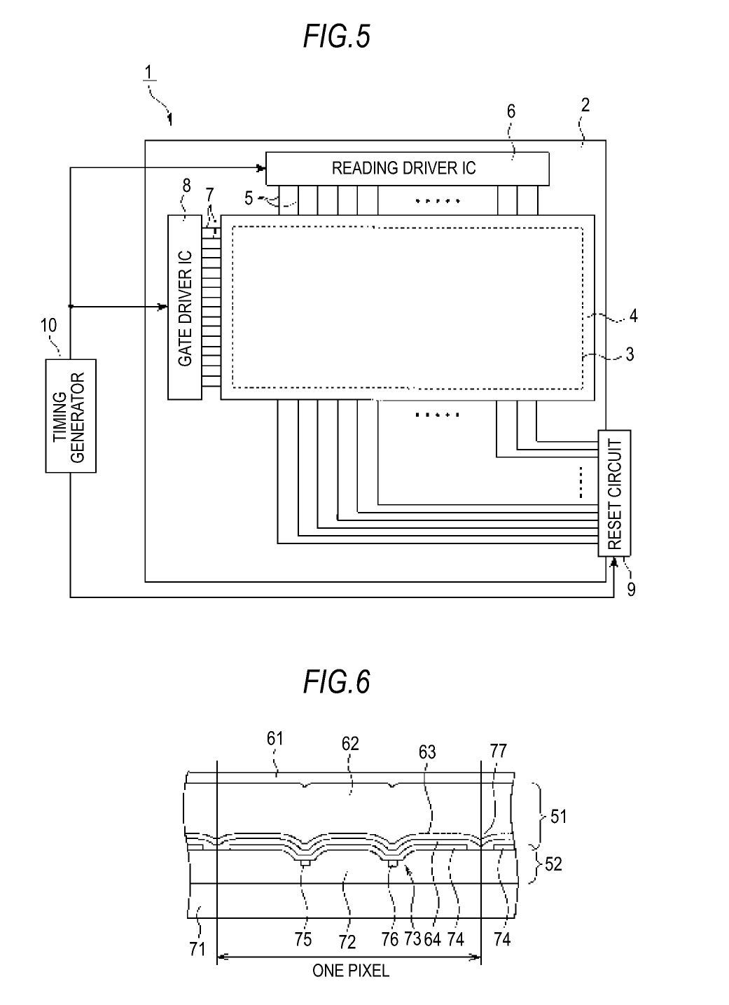

Although it has been described in the above-mentioned embodiment that the reset circuit 9 is disposed on the opposite side of the reading driver IC 6 with the photoelectric conversion panel 2 interposed therebetween, the invention is not limited to this configuration, but the reset circuit may be disposed at an end on the opposite side of the gate driver IC 8 with the photoelectric conversion panel 2 interposed therebetween as shown in FIG. 5.

Although it has been described in the above-mentioned embodiment that the PIN photo diode PD is used as the light detection element, the invention is not limited to this configuration, but an MIS element may be used as the light detection element.

Although it has been described in the above-mentioned embodiment that the capacitor C is connected in parallel to the PIN photo diode PD, the invention is not limited to this configuration, but the capacitor C may not be provided when the parasitic capacitor of the PIN photo diode PD has such capacitance as to store the charges.

Although it has been described in the above-mentioned embodiment that the scintillator 4 converting an X-ray into a visible ray is employed, the invention is not limited to this configuration, but the invention may be applied to any imaging apparatus other than the autoradiographic apparatus by employing a scintillator converting a radiation ray other than the X-ray into light which can be detected by the photoelectric conversion device.

Although it has been described in the above-mentioned embodiment that the photoelectric conversion device is applied to the autoradiographic apparatus, the invention is not limited to this configuration, but may be applied as a photoelectric conversion device of an imaging apparatus such as another same-magnification imaging apparatus.

Although it has been described in the above-mentioned embodiment that the reading driver IC 6 and the reset circuit 9 are provided individually, the embodiments are not limited to this configuration. When the reading driver IC is disposed on both sides of the photoelectric conversion area 3, any one thereof may be dedicated to the reset circuit.

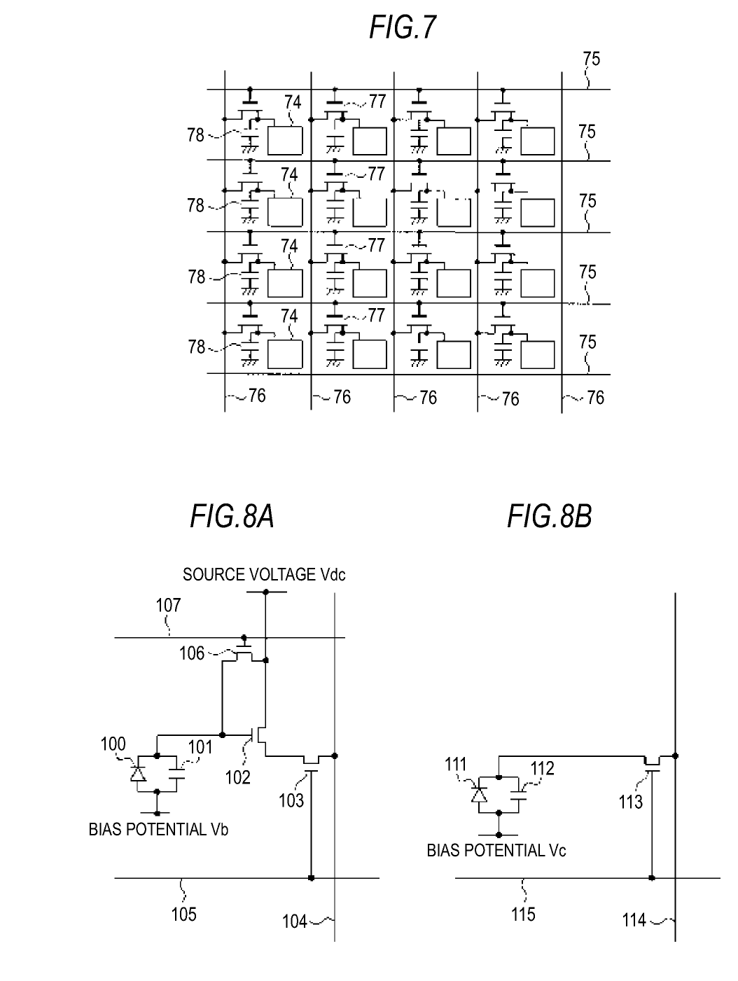

Although it has been described in the above-mentioned embodiment that a radiation ray is converted into a visible ray by the use of the photoelectric conversion panel 2 and the scintillator 4 and the visible ray is converted photoelectrically to store the charges, the embodiment is not limited to this configuration, but the scintillator 4 may not be provided and a radiation detector 50 may be employed. As shown in FIG. 6, the radiation detector 50 includes a photoelectric layer 51 that converts an incident X-ray into an electrical signal (electron e or hole h) and a TFT circuit board 52 that extracts the outputs converted into the electrons e or the holes h by the photoelectric layer 51 depending on the positions of the incident X-ray incident on the photoelectric layer 51. The photoelectric layer 51 includes an upper electrode 61, an upper polycrystalline photoelectric conversion film 62 formed of PbI₂, the contact with air of which is suppressed by the upper electrode 61, a conductive interlayer film 63 containing Pb disposed below the upper polycrystalline photoelectric conversion film 62, and a lower photoelectric conversion film 64 formed of amorphous PbI₂, which is disposed under the conductive interlayer film 63. The TFT circuit board 52 includes a TFT circuit layer 73 disposed on an inter-phase insulating film 72 stacked on a holding substrate 71 formed of a glass plate. The TFT circuit layer 73 includes a pixel electrode (ITO lower electrode) 74, a row-selecting signal line 75 and a reading signal line 76 perpendicular to each other, a thin film transistor (TFT) 77 disposed at each intersection of the lines 75 and 76, and a capacitor 78 as the charge storage portion that holds the charges flowing in the pixel electrode (ITO lower electrode) 74 until the gate electrode of the TFT 77 is turned on. In an internal equivalent circuit of the radiation detector 50, as shown in FIG. 7, a parallel circuit of a pixel electrode 74 and a capacitor 78 in each pixel 11 is connected to the reading signal line 76 via the TFT 77 and the gate of the TFT 77 is connected to the row-selecting signal line 75. A CdTe element may be used as the radiation detection element.

It should be understood that various changes and modifications to the presently preferred embodiments described herein will be apparent to those skilled in the art. Such changes and modifications can be made without departing from the spirit and scope of the present subject matter and without diminishing its intended advantages. It is therefore intended that such changes and modifications be covered by the appended claims.

The invention is claimed as follows:

1. A photoelectric conversion device comprising:
a photoelectric conversion panel in which light detection portions each having a charge storage portion storing light as electric charges are two-dimensionally arranged;
a reading control unit that reads the electric charges stored in the charge storage portions of the photoelectric conversion panel for each reading signal line; and
a reset unit that is connected to the reading signal lines and discharges residual charges of the charge storage portions for each reading signal line,
wherein the reading control unit and the reset unit are arranged at different end portions of the photoelectric conversion panel.

2. The photoelectric conversion device according to claim 1, wherein the reset unit is arranged on the opposite side of the reading control unit with the photoelectric conversion panel interposed therebetween.

3. A photoelectric conversion device comprising:
a photoelectric conversion panel in which light detection portions each having a charge storage portion storing light as electric charges are two-dimensionally arranged;
a reading control unit that reads the electric charges stored in the charge storage portions of the photoelectric conversion panel for each reading signal line; and
a reset unit that is connected to the reading signal lines and discharges residual charges of the charge storage portions for each reading signal line,
wherein the reading control unit and the reset unit have different circuit configurations.

4. The photoelectric conversion device according to claim 3, wherein the reset unit is built in the photoelectric conversion panel.

5. The photoelectric conversion device according to claim 1, wherein each light detection portion includes a parallel circuit in which a light detection element and a charge storage element are connected in parallel and the parallel circuit includes an end supplied with a bias potential and the other end connected to the corresponding reading signal line via a switching element.

6. The photoelectric conversion device according to claim 1, wherein the reset unit includes switches which are individually interposed between the reading signal lines and a reset power source and controls the switches to simultaneously be turned on at the time of resetting.

7. The photoelectric conversion device according to claim 6, wherein the reset power source is commonly used as a bias power source and the length of bias lines is equal to the length of the reading signal lines.

8. The photoelectric conversion device according to claim 6, wherein the potential of a bias power source is set to be higher than the potential of the reset power source.

9. The photoelectric conversion device according to claim 1, wherein each light detection element is formed of one of a PIN element and an MIS element.

10. An autoradiographic apparatus comprising:
the photoelectric conversion device according to claim 1; and
a scintillator that is disposed on a light detection face of the photoelectric conversion panel of the photoelectric conversion device so as to convert a radiation ray into a visible ray.

11. A radiation detection device comprising:
a radiation detection panel in which radiation detection portions each having a charge storage portion storing a radiation ray as electric charges are two-dimensionally arranged;
a reading control unit that reads the electric charges stored in the charge storage portions of the radiation detection panel for each reading signal line; and
a reset unit that is connected to the reading signal lines and discharges residual charges of the charge storage portions for each reading signal line,
wherein the reading control unit and the reset unit are arranged at different end portions of the radiation detection panel.

12. The radiation detection device according to claim 11, wherein the reset unit is arranged on the opposite side of the reading control unit with the radiation detection panel interposed therebetween.

13. A radiation detection device comprising:
a radiation detection panel in which radiation detection portions each having a charge storage element and a radiation detection element are two-dimensionally arranged;
a reading control unit that reads the electric charges stored in the charge storage elements of the radiation detection panel for each reading signal line; and
a reset unit that is connected to the reading signal lines and discharges residual charges of the charge storage elements for each reading signal line,
wherein the reading control unit and the reset unit have different circuit configurations.

14. The radiation detection device according to claim 13, wherein the reset unit is built in the radiation detection panel.

15. The radiation detection device according to claim 11, wherein each radiation detection portion includes a parallel circuit in which a radiation detection element and a charge storage element are connected in parallel and the parallel circuit includes an end supplied with a bias potential and the other end connected to the corresponding reading signal line via a switching element.
